(19) United States
(12) Patent Application Publication
(10) Pub. No.: US 2026/0010681 A1
(43) Pub. Date: Jan. 8, 2026

(54) METHOD FOR OPTIMIZING DOUBLE-LAYER PA PAVEMENT STRUCTURE INTO THREE-LAYER STRUCTURE BASED ON EQUAL PERMEATION RATE

(71) Applicant: Changsha University of Science & Technology, Changsha City (CN)

(72) Inventors: Jun CAI, Changsha City (CN); Yuting HU, Changsha City (CN); Yuqiang LIN, Changsha City (CN); Fan GU, Changsha City (CN); Huanan YU, Changsha City (CN); Guoping QIAN, Changsha City (CN); Rong LUO, Changsha City (CN)

(73) Assignee: Changsha University of Science & Technology, Changsha City (CN)

(21) Appl. No.: 18/882,800

(22) Filed: Sep. 12, 2024

(30) Foreign Application Priority Data
Jul. 3, 2024 (CN) 202410891311.5

(51) Int. Cl. G06F 30/27; G06F 30/13

(52) U.S. Cl. CPC G06F 30/27; G06F 30/13

(57) ABSTRACT

The present invention discloses a method for optimizing the double-layer PA pavement structure into a three-layer structure based on equal permeation rate, belonging to the technical field of structural optimization of double-layer PA pavement. The method includes compressing the double-layer PA pavement and determining the thickness and position of an added surface layer. A prediction model for multi-factor permeation rate is constructed using the XGBoost algorithm. The air voids prediction model is derived by adjusting the dependent variable of the permeation rate model. The dosage of interlayer emulsified asphalt is determined, considering its effect on the permeation rate. The air voids and thickness of each layer are calculated, resulting in a final optimized three-layer structure that reduces structural redundancy, increases connected air voids, and improves pavement performance.

### TECHNICAL FIELD

The present invention relates to the technical field of structural optimization of double-layer porous asphalt pavement, in particular to a method for optimizing the double-layer PA pavement structure into three-layer structure based on equal permeation rate.

### BACKGROUND ART

Double-layer porous asphalt (PA) pavement has been gradually applied in recent years due to its high drainage efficiency and excellent noise reduction effect. The thickness and air voids of double-layer PA pavement are generally large due to the limitation of pavement structure in China. According to the practical feedback, the larger thickness is not only not conducive to the recovery after the void clogging, but also needs to adopt a larger air void to maintain its functional characteristics, which in turn reduces the road performance, and ultimately leads to the ‘double lose’ situation with poor functional characteristics and road performance. Therefore, how to design a double-layer PA pavement that takes into account road performance and functional characteristics is an important challenge for current road science and technology workers.

Especially for the upper PA pavement, it not only needs to bear the load, and play the role of drainage and noise reduction, but also is directly affected by temperature changes, solar radiation, rain erosion and other environmental factors and tire friction, so the overall service environment is more severe. Therefore, it is more urgent to optimize the upper PA pavement structure and improve its road performance.

For this reason, the present invention takes the double-layer PA pavement as the research object, and on the basis of maintaining its functional characteristics unchanged, the pavement structure reorganization and optimization design research based on thin layers is carried out. In particular, the air voids of the upper PA pavement are greatly reduced, which significantly improves its road performance.

### SUMMARY OF THE INVENTION

An objective of the present invention is to provide a method for optimizing double-layer PA pavement structure into three-layer structure based on equal permeation rate to solve the problems mentioned in the above background art.

In order to achieve the above objective, the present invention provides a method for optimizing double-layer PA pavement structure into three-layer structure based on equal permeation rate, comprising the following steps:
S1, studying a relationship between a pavement structure and a material composition segregation of different nominal maximum particle sizes and different paving thickness, determining a multiple relationship between paving thickness and nominal maximum particle size, and compressing the thickness of an upper layer and a lower layer of an original double-layer PA pavement, and obtaining the thickness and the nominal maximum particle size of an added layer by combining a principle that the total thickness of the pavement before and after optimization is unchanged, so as to form an initial three-layer PA pavement;
S2, studying the effect of air voids, paving thickness and nominal maximum particle size on a permeation rate, and establishing a prediction model of permeation rate based on an XGBoost algorithm; combining with the permeation rate of the upper layer of double-layer PA pavement before optimization, and keep the permeation rate unchanged before and after optimization, obtaining the permeation rate of three-layer PA pavement;
exchanging a dependent variable permeation rate and an independent variable air voids in a prediction model of permeation rate based on XGBoost algorithm, and obtaining an air voids prediction model for determining the air voids based on permeation rate, paving thickness and nominal maximum particle size, combining with the permeation rate of the upper layer and an intermediate layer of the three-layer PA pavement, determining a corresponding air void, and completing an optimization design of the material composition of the upper layer and the intermediate layer;
S3, studying the effect of different distribution amounts of emulsified asphalt between the intermediate layer and lower layer on the permeability of the lower layer and interlayer bonding capacity according to the feasibility of the actual construction process of the three-layer PA pavement, and based on the effect of different dosages of emulsified asphalt on an interlayer shear strength of the intermediate layer and lower layer and permeability of the lower layer, determining the dosage of emulsified asphalt between the intermediate layer and lower layer, and determining the amount of interlayer emulsified asphalt of the intermediate layer and lower layer;
S4, studying a relationship between the air voids and the permeation rate of the lower layer PA pavement under a given amount of emulsified asphalt, based on the principle that the permeation rate of each layer of the three-layer PA pavement is equal, determining the air voids size of the lower layer, and determining the thickness and material composition of the final three-layer PA pavement.

Preferably, S1 specifically comprises:
S11, quantitatively evaluating an internal structure distribution and segregation characteristics of double-layer PA pavement with different thickness according to a segregation degree of vertical structure, a coefficient of uneven distribution of particles and an variation coefficient of the vertical distribution of particles, and determining a multiple relationship between paving thickness and nominal maximum particle size;
S12, according to the multiple relationships between the paving thickness and the nominal maximum particle size, keeping the nominal maximum particle size of the upper layer and lower layer of the double-layer PA pavement unchanged, and compressing the thickness of the upper layer and lower layer, at the same time, combining with a principle that the total thickness of the pavement before and after optimization is unchanged, obtaining the thickness and the nominal maximum particle size of the added layer, and forming the initial three-layer PA pavement.

Preferably, the specific steps of S2 are:
S21, establishing the prediction model of permeation rate based on the XGBoost algorithm according to the relationship between air voids, paving thickness, nominal maximum particle size and permeation rate, at the same time, obtaining the permeation rate of the upper layer of the original double-layer PA pavement according to the real experiment;
S22, exchanging the independent variable air voids and the dependent variable permeation rate of the prediction model of permeation rate in the XGBoost algorithm to form an air voids prediction model based on the permeation rate, the nominal maximum particle size and the paving thickness to predict the air voids size, according to the principle that the permeation rate before and after pavement optimization is unchanged, putting the permeation rate of the upper layer of the double-layer PA pavement, and the paving thickness and the nominal maximum particle size of the upper layer and intermediate layer of the initial three-layer PA pavement obtained in S1 into the air voids prediction model as input data, obtaining the air voids of the upper layer and intermediate layer of the initial three-layer PA pavement.

Preferably, the relationship between the permeation rate and different dosages of emulsified asphalt is obtained by using the initial permeation rate of the three-layer PA pavement in S3, and at the same time, the relationship between different dosages of emulsified asphalt and the interlayer shear strength between the layers is also obtained to determine an optimal amount of emulsified asphalt;
the calculation formula for interlayer shear strength is as follows:

$$τ = \frac{F}{A}$$

where τ is a shear strength; F is a maximum failure load; A is an interlayer contact area.

Preferably, S4 specifically comprises:
based on the principle that the permeation rate of each layer of the three-layer PA pavement is equal, obtaining the relationship between the permeation rate and the given emulsified asphalt, and then obtaining the relationship between the dosage of emulsified asphalt and the air voids, putting the paving thickness, the nominal maximum particle size, the permeation rate and the given emulsified asphalt amount in S2 into the air voids prediction model as input data to determine the air voids of the lower layer.

Preferably, the accuracy of the prediction model of permeation rate is evaluated by R², MSE, RMSE, MAE, and MAPE.

Therefore, the present invention adopts the above-mentioned method for optimizing double-layer PA pavement structure into three-layer structure based on equal permeation rate, which has the following beneficial effects:
in the design process of three-layer PA pavement, the effect of air voids, paving thickness and particle size composition is comprehensively considered to reduce the waste of structural redundancy air voids, combined with the principle of equal permeation rate before and after optimization, the overall air voids can be reduced, the connected air voids can be effectively increased, and the permeability can be guaranteed, at the same time, it is of great significance to improve the overall service quality of pavement by ensuring the bonding ability of pavement and realizing the enhancement of its road performance.

Further detailed descriptions of the technical scheme of the present invention can be found in the accompanying drawings and embodiments.

### BRIEF DESCRIPTION OF DRAWINGS

FIG. 1 is a schematic diagram of the overall process of an embodiment of the present invention;

FIG. 2 is a flow chart of a segregation degree analysis of an embodiment of the present invention;

FIG. 3 is a multi-layer pavement structure diagram before and after the optimization of an embodiment of the present invention;

FIG. 4 is a schematic diagram of a bidirectional permeameter structure of an embodiment of the present invention;

FIG. 5 is a graph of actual experimental values and predicted results of a permeation rate model validation of an embodiment of the present invention;

FIG. 6 is experimental results of permeation rate and time at different air voids of embodiments of the present invention; wherein, FIG. 6(a) is the experimental results of the permeation rate and time of PAC-10 specimens at different air voids; FIG. 6(b) is the experimental results of the permeation rate and time of PAC-13 specimens at different air voids; FIG. 6(c) is the experimental results of the permeation rate and time of PAC-16 specimens at different air voids;

FIG. 7 is experimental results of permeation rate and time at different paving thickness of embodiments of the present invention; wherein, FIG. 7(a) is the experimental results of the permeation rate and time of PAC-10 specimens at different paving thickness; FIG. 7(b) is the experimental results of the permeation rate and time of PAC-13 specimens at different paving thickness; FIG. 7(c) is the experimental results of the permeation rate and time of PAC-16 specimens at different paving thickness;

FIG. 8 is experimental results of permeation rate and time at different nominal maximum particle sizes of embodiments of the present invention;

FIG. 9 is a schematic diagram of an interlayer distributing emulsified asphalt of an embodiment of the present invention;

FIG. 10 is a result comparison diagram of a water permeability coefficient of an embodiment of the present invention;

FIG. 11 is a result comparison diagram of shear strength of an embodiment of the present invention;

FIG. 12 is a schematic diagram of the structural optimization of an embodiment of the present invention;

FIG. 13 is a permeability test result diagram of a porous asphalt mixture before and after the optimization of an embodiment of the present invention.

### DETAILED DESCRIPTION OF THE EMBODIMENTS

### Embodiment

The following clearly and completely describes the technical solutions in embodiments of the present invention with reference to the embodiments of the present disclosure, the described embodiments are only some but not all of the embodiments of the present invention.

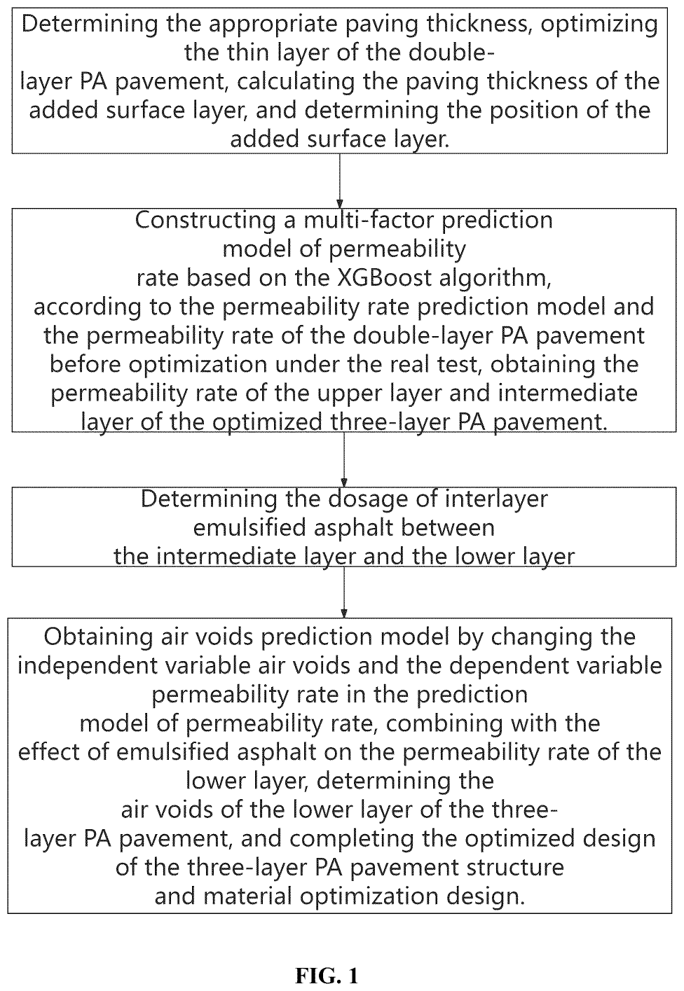

With reference to FIG. 1, the present invention discloses a method for optimizing double-layer PA pavement structure into three-layer structure based on equal permeation rate, comprising the following steps (the specific embodiment takes the Suizimei Expressway in Sichuan Province as an example):
S1, a relationship between a pavement structure and a material composition segregation of different nominal maximum particle sizes and different paving thickness are studied, a multiple relationship between paving thickness and nominal maximum particle size are determined, and the thickness of an upper layer and a lower layer of an original double-layer PA pavement is compressed, and the thickness of an added layer and the nominal maximum particle size is obtained by combining a principle that the total thickness of the pavement before and after optimization is unchanged, so as to form an initial three-layer PA pavement;
the thickness of the conventional double-layer porous pavement is optimized to obtain a suitable paving thickness. The uniform asphalt pavement structure should be that the coarse aggregate particles are evenly distributed in the horizontal plane and the vertical plane. As shown in Table 1, PAC-10, PAC-13, PAC-16 and porous asphalt mixture with the nominal maximum particle size of 2.0 times, 2.5 times, and 3.0 times are selected to reflect their effect on the uniformity of asphalt mixture. Marshall specimens with a diameter of 152.4 mm are designed and prepared for each mixture.

TABLE 1
Preparation of samples for segregation characteristics test

| Particle size | Air voids % | Thickness (cm) |
|---|---|---|
| PAC-10 | 18 | 2, 2.5, 3 |
| PAC-13 | | 3, 3.5, 4 |
| PAC-16 | | 3, 4, 5 |

The degree of vertical structure segregation and the solution of various coefficients are calculated according to the existing art. An uneven distribution coefficient Uₓ of particles is used to evaluate the uniformity of coarse aggregate distribution in the plane, and the vertical distribution variable coefficient Vx of particles is used to evaluate the degree of vertical structure segregation of pavement at this position. The internal structure distribution and segregation characteristics of different specimens are quantitatively evaluated by using the above coefficients, and the relationship between the overall uniformity of the specimens and the paving thickness is obtained.

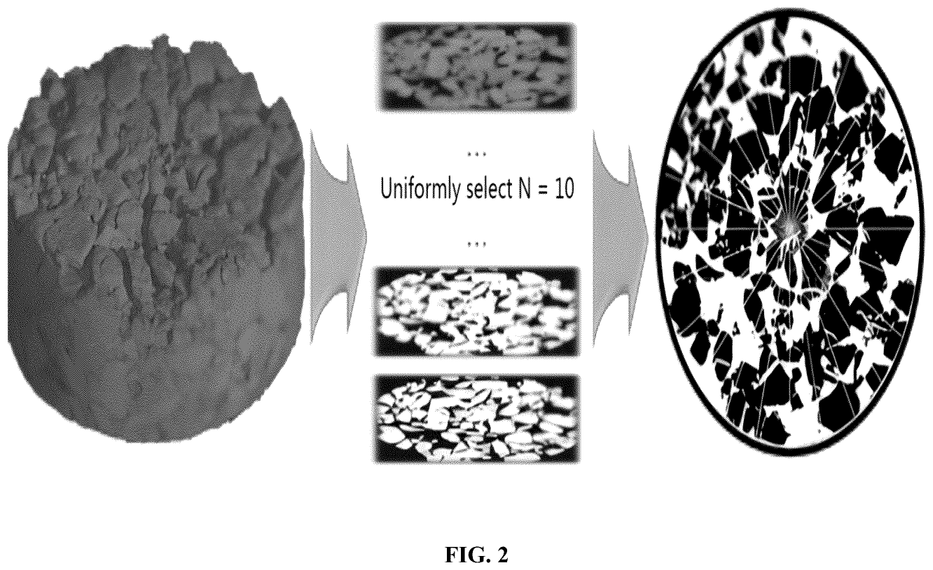

Core sampling (diameter of 100 mm) is performed on large Marshall specimens with different thicknesses, and core samples are scanned to obtain internal particle information to obtain a set of continuous cross-sectional sections. Ten scanning sections are evenly selected from different positions of the core sample for binarization and digital image processing. The sector method is used to analyze the section, taking the positive direction of the x-axis as a starting point and the center of a circle as a rotation axis, the graph is divided into 24 sector regions along a counterclockwise direction at 15°. The ratio of the sum of the particle area of each cumulative coarse aggregate to the sector area is defined as a particle area ratio Sₓ, and the particle area ratio in each unit region is calculated respectively. Through the statistical analysis of the particle area ratio, the uneven distribution coefficient of the particles is calculated to evaluate the uniformity of the aggregate distribution of the asphalt mixture. Through the statistical analysis of the change of the area ratio index of coarse aggregate particles between the vertically selected sections of the same specimen, the vertical distribution variable coefficient of particles is calculated. The process is shown in FIG. 2.

The results of the vertical distribution variable coefficient of the three gradation types PAC-10, PAC-13 and PAC-16 corresponding to different thickness depths are shown in Table 2. The mean value of the particle area ratio between sections with different thicknesses at different gradations is not much different, and the overall composition of particles with different thicknesses is approximately the same, however, for the mean square deviation of particle area ratio between sections, the difference between the mean square deviation of 2.5 times of nominal maximum particle size and other thicknesses is relatively large. Combined with the analysis results of the uneven distribution coefficient of particles, it can be seen that the use of coarse aggregate is more, which has a great effect on the spatial distribution state distribution and segregation degree of the core sample.

TABLE 2
Vertical distribution variable coefficient of
different thickness at different gradations

| | | Mean square | Mean value of | |
|---|---|---|---|---|
| | Different | deviation of the | particle area | vertical |
| Gradation | thickness/ | particle area ratio | ratio between | variation |
| type | cm | between sections | sections | coefficient/% |
| PAC-10 | 2 | 0.0063 | 0.809 | 0.7786 |
| | 2.5 | 0.0048 | 0.8391 | 0.5756 |
| | 3 | 0.0069 | 0.7382 | 0.9347 |
| PAC-13 | 3 | 0.021 | 0.7497 | 2.8058 |
| | 3.5 | 0.0156 | 0.7654 | 2.0425 |
| | 4 | 0.0196 | 0.7627 | 2.5689 |
| PAC-16 | 3 | 0.0182 | 0.6385 | 2.8544 |
| | 4 | 0.0149 | 0.6916 | 2.1613 |
| | 5 | 0.0186 | 0.6638 | 2.7994 |

It can be seen from Table 2 that the vertical distribution variable coefficient of the paving thickness at different gradations is 2.5 times of the nominal maximum particle size, which is smaller than the thickness of 2.0 times and 3.0 times, and the uniformity is better.

Therefore, when the paving thickness is 2.5 times of the nominal maximum particle size, the overall uniformity of the specimen is the best.

The thickness of the conventional double-layer PAC pavement structure is designed by 2.5 times of the nominal maximum particle size, the optimized upper layer is 2.5 cm PAC-10 and the lower layer is 4 cm PAC-16 to ensure that the thickness of the pavement structure design remains unchanged, a layer of PAC-13 is added in the middle of the double-layer PAC pavement structure layer as a ‘thickness patching layer’ with a thickness of 3.5 cm, which is also 2.5 times of the maximum nominal particle size.

The upper layer adopts the PAC-10 structure with an air void of 22% and a thickness of 3.5 cm, and the lower layer adopts the PAC-16 structure with an air void of 22% and a thickness of 6.5 cm. The permeation rate is obtained by the prediction model of permeation. At the same time, the maximum nominal particle size of the upper layer and the lower layer is kept unchanged, and then the thickness of the two layers is compressed, according to the most suitable paving thickness, in order to ensure that the thickness of the pavement structure design before and after optimization is unchanged, a PAC-13 thickness patching layer is added to the optimized double-layer PAC pavement.

S2, the effect of air voids, paving thickness and nominal maximum particle size on a permeation rate is studied, and a prediction model of permeation rate based on the XGBoost algorithm is established; combined with the permeation rate of an upper layer of double-layer PA pavement, and keep the permeation rate unchanged before and after optimization, the permeation rate of three-layer PA pavement is obtained;
a dependent variable permeation rate and an independent variable air voids in a prediction model of permeation rate based on the XGBoost algorithm are exchanged, and an air voids prediction model for determining the air voids based on permeation rate, paving thickness and nominal maximum particle size is obtained, combined with the permeation rate of an upper layer and an intermediate layer of the three-layer PA pavement, a corresponding air void is determined, and an optimization design of the material composition of the upper layer and the intermediate layer is completed.

The effects of different factors on the permeability characteristics of porous asphalt mixtures with different air voids, thickness and particle size are studied, as shown in Table 3.

TABLE 3
Test specimens for permeability characteristic test

| Gradation type | Air voids/% | Thickness/cm |
|---|---|---|
| PA-10 | 15, 18, 21, 24 | 2, 3, 4 |
| PA-13 | | 3, 4, 5 |
| PA-16 | | 4, 5, 6 |

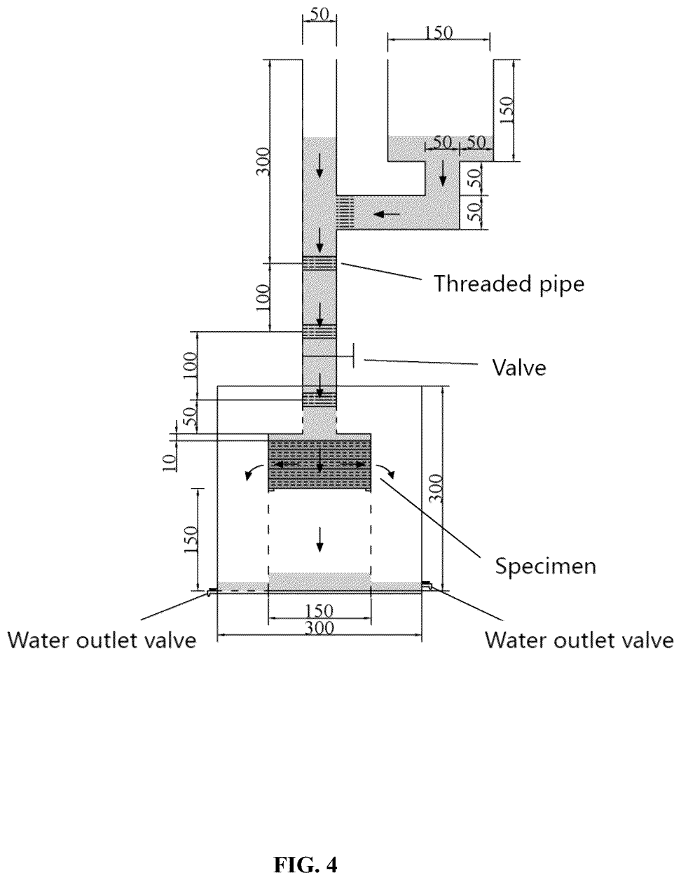

A self-developed bidirectional permeameter that can simultaneously measure vertical and horizontal permeability is used to reflect the permeability characteristics under real conditions, as shown in FIG. 4. a certain permeability water quality mᵢ(g) is weighed, the permeation time t(s) is recorded, and the respective permeation rate (vertical permeation rate v₁, horizontal permeation rate v₂) is calculated through Formula (1).

$${V}_{i} = \frac{4 {m}_{i}}{ρ π {d}^{2} t} = \frac{{m}_{i}}{176.625 t} \qquad ( 1 )$$

where ρ is a density of water (g/cm³), d is a diameter of the measuring instrument, and is 150 mm.

The prediction model of permeation rate is constructed by using the extreme gradient boosting (XGBoost) algorithm, and the effects of air voids, specimen thickness and particle size composition on the permeability characteristics are analyzed. Taking air voids, specimen thickness and nominal maximum particle size as the input characteristics of the XGBoost model, 36 sets of specimens with different specifications are selected, 4 parallel specimens are formed in each set, and 144 sets of sample data are used for training, as shown in Table 4. At the same time, the sum of horizontal and vertical permeation rates is used as a predicted value, and the accuracy of the prediction model of permeation rate is evaluated by R², MSE, RMSE, MAE, and MAPE, as shown in Table 5.

TABLE 4
Prediction model input data

| Permeation rate | Particle | | Air |
|---|---|---|---|
| (cm/s) | size | Thickness(cm) | voids |
| Actual measured | PAC-10 | 2 | 15% |
| value | PAC-13 | 3 | 18% |
| | PAC-16 | 4 | 21% |
| | | 5 | 24% |
| | | 6 | |

TABLE 5
Model prediction accuracy evaluation index description

| Evaluation | | | |
|---|---|---|---|
| index | Concrete name | Calculation formula | Symbol description |
| R2 | Determination coefficient | ${R}^{2} = 1 - \frac{{\sum }_{i} {( {y}_{i} - {\hat{y}}_{i} )}^{2}}{{\sum }_{i} {( {y}_{i} - {\overline{y}}_{i} )}^{2}}$ | yᵢ is the actual value of the output parameter |
| MSE | Mean square error | $MSE = \frac{1}{n} {\sum }_{i = 1}^{n} ( {y}_{i} - {\hat{y}}_{i} ) \text{?}$ | ŷᵢ is the predicted value of the output parameter |
| RMSE | Root mean square error | $RMSE = \sqrt{\frac{1}{n} {\sum }_{i = 1}^{n} {( {y}_{i} - {\hat{y}}_{i} )}^{2}} \text{?}$ | y̅ᵢ is the mean value of the actual value of the output parameter |
| MAE | Mean absolute error | $MAE = \frac{1}{n} {\sum }_{i = 1}^{n} \vert {y}_{i} - {\hat{y}}_{i} \text{?}$ | n is the total amount of data samples |
| MAPE | Mean absolute percentage error | $MAPE = \frac{100 \%}{n} {\sum }_{i = 1}^{n} \vert \frac{{y}_{i} - {\hat{y}}_{i}}{{y}_{i}} \text{?}$ | |

$\text{?} \text{indicates text missing or illegible when filed}$

After training 144 sets of samples, the established training model is formed. Randomly predict the permeation rate results of part data in the training set, as shown in Table 6, and the accuracy of the model is tested. The evaluation results of each evaluation index are shown in Table 7. The determination coefficient R² of the test set and other related evaluation indexes have high accuracy, indicating that the training model has a good fitting effect on the data in the training set.

TABLE 6
Part of the test data prediction results

| | | | | Permeation | Prediction |
|---|---|---|---|---|---|
| Order | Particle size | Thickness | Air | rate | results |
| number | gradation | (cm) | voids | (cm/s) | (cm/s) |
| 1 | PAC-16 | 5 | 21% | 0.8612 | 0.8940 |
| 2 | PAC-10 | 4 | 21% | 0.6980 | 0.6794 |
| 3 | PAC-10 | 3 | 15% | 0.6444 | 0.6533 |
| 4 | PAC-13 | 5 | 15% | 0.5612 | 0.5479 |
| 5 | PAC-16 | 4 | 18% | 0.7727 | 0.8093 |
| 6 | PAC-13 | 4 | 24% | 0.7089 | 0.7385 |
| 7 | PAC-16 | 6 | 18% | 0.7193 | 0.7077 |

TABLE 7
permeation rate model evaluation results

| | MSE | RMSE | MAE | MAPE | R² |
|---|---|---|---|---|---|
| Training set | 0 | 0.001 | 0.001 | 0.117 | 1 |
| Test set | 0.001 | 0.035 | 0.028 | 2.041 | 0.922 |

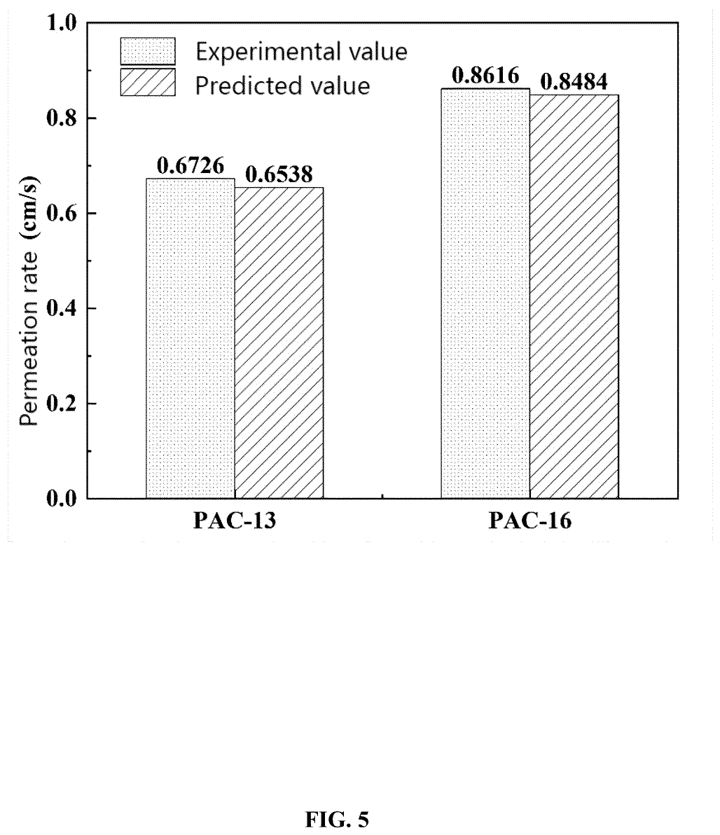

In order to further verify the accuracy and correctness of the prediction model of permeability, the conventional double-layer PAC pavement structure ‘5 cm+5 cm’ (the upper layer uses PAC-13 with an air void of 20%, and the lower layer selects PAC-16 with an air void of 20%) is used as a reference, two sets of PAC-13 and PAC-16 gradations with the air voids of 20% and a standard rutting plate specimen with a forming thickness of 5 cm are selected to measure the permeation rate, which is compared with the model prediction results, as shown in FIG. 5. It shows that the prediction model has high accuracy.

Air voids are the most important factor affecting the permeation rate, for the PAC mixture, adjusting the air voids is the most effective way to obtain the target void characteristics, but at the same time, using the appropriate paving thickness and changing the particle size composition of the mixture can also significantly change the permeation rate.

The independent variable air voids and the dependent variable permeation rate of the prediction model of permeation rate in the XGBoost algorithm are exchanged to form an air voids prediction model based on the permeation rate, the nominal maximum particle size and the paving thickness to predict the air voids size, according to the principle that the permeation rate before and after pavement optimization is unchanged, the permeation rate of the upper layer of the double-layer PA pavement, and the paving thickness and the nominal maximum particle size of the upper layer and intermediate layer of the initial three-layer PA pavement obtained in S1 are put into the air voids prediction model as input data, the air voids of the upper layer and intermediate layer of the initial three-layer PA pavement are obtained.

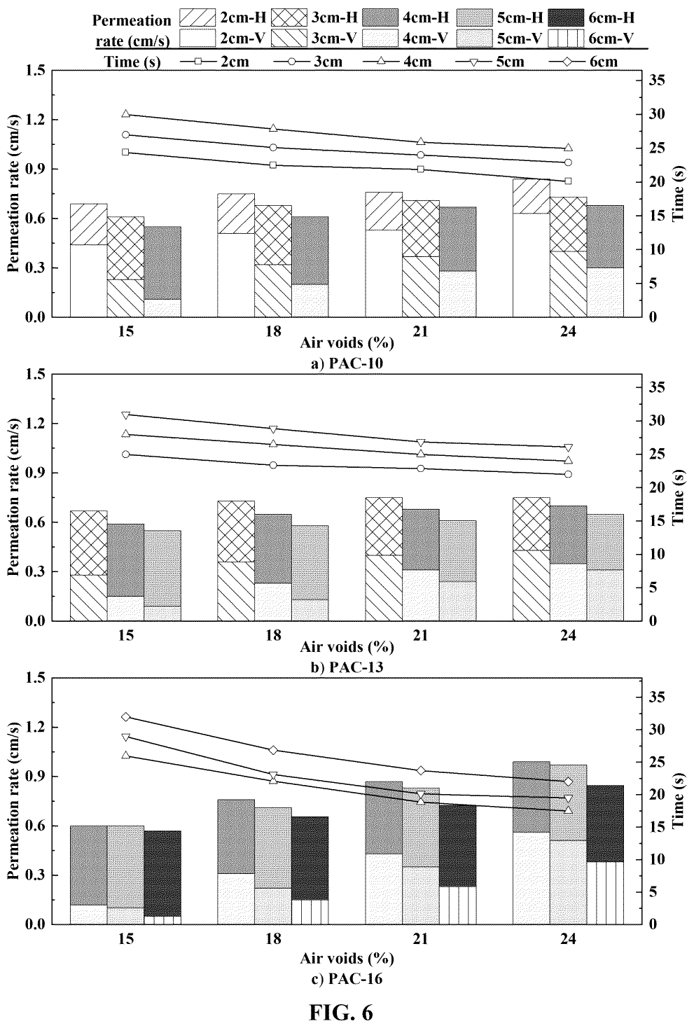

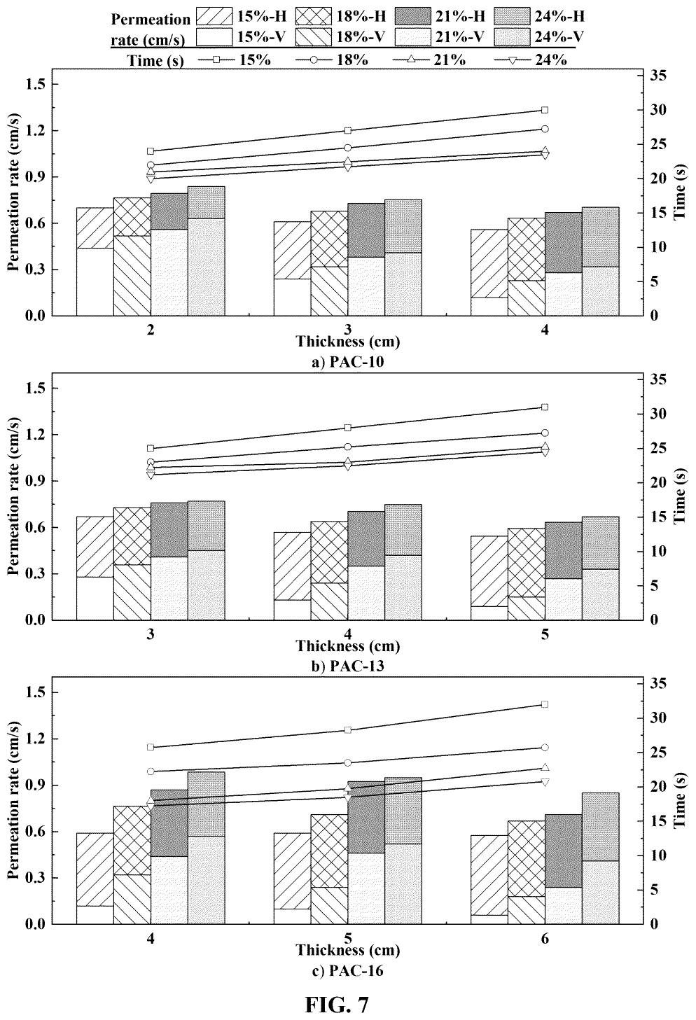

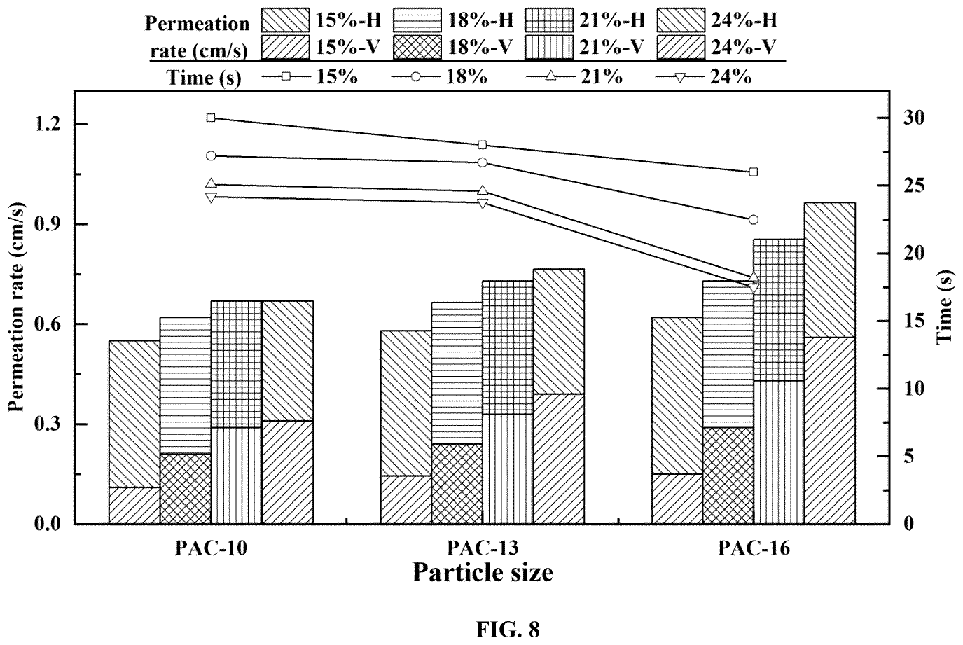

The permeation rate and permeation time under different air voids and different thickness are shown in FIG. 6 and FIG. 7, respectively, at the same time, the change of permeation rate and permeation time for different nominal maximum particle size under the same thickness of 4 cm is shown in FIG. 8. Wherein, the column represents the permeation rate, and V and H represent the vertical and horizontal permeation rates, respectively. The point-line diagram represents the time flowing through different specimens.

It can be seen from FIG. 6 that with the increase of air voids, the permeation rate of PA mixture with different nominal maximum particle sizes has been improved to a certain extent, indicating that with the increase of air voids, the connectivity of the internal voids of the specimen can be significantly improved, and the permeability of porous asphalt pavement can be enhanced. Wherein, the vertical permeation rate has been significantly improved, while the horizontal permeation rate has a slow downward trend, and the water flow will tend to choose the vertical permeation path for infiltration. At the same time, the permeation time is also shortened to a certain extent, and the permeation time of PAC-16 gradation decreases faster. In the range of air voids of 15%-21%, the improvement effect of drainage efficiency is more obvious, and after more than 21%, the increase of drainage efficiency becomes slow. This result is consistent with the conclusion that the current PAC selection air voids are mostly concentrated between 20% and 22%. Although the horizontal permeation rate decreases slowly with the increase of air voids, it always occupies the main position in the permeation process, and still accounts for 40.3%-46.7% of the total permeation rate when the air void is 24%.

It can be seen from FIG. 7 that as the thickness of the specimen increases, the total permeation rate and vertical permeation rate of the PAC specimen show a downward trend, while the horizontal permeation rate increases and the permeation time gradually increases. Compared with each figure, under the same void condition, the permeation rate of PAC-16 is significantly lower than that of other gradations. When the thickness of the specimen is thin (2 cm-3 cm), it is mainly based on vertical permeation due to the small or even no void on the side of the specimen; as the thickness of the specimen increases, the vertically connected voids decrease, and the more voids on the side, the permeability of the specimen changes from vertical permeation to horizontal permeation, so the horizontal permeation rate also increases. For example, when the thickness of PAC-10 gradation increased from 2 cm to 3 cm, the vertical permeation rate decreased by 37.3%, while the horizontal permeation rate increased by 56.5%.

It can be seen from FIG. 8 that with the increase of the maximum nominal particle size, the permeation rate increases, and the corresponding permeation time decreases in turn, at the same time, the vertical permeation rate and the horizontal permeation rate increase, and the increase of the vertical permeation rate is more obvious. When the air void is greater than 18%, it can be clearly seen that the permeation rate of PAC-16 is much larger than that of PAC-13 and the rate of increase is faster. This shows that the greater the maximum nominal particle size of the PAC specimen, the greater the effect on its permeation rate, and when the maximum nominal particle size is small, the effect on the gradation may not be so obvious.

In summary, with the increase of air voids and nominal maximum particle size, the total permeation rate of PA pavement is significantly improved, while the increase of thickness reduces it. Wherein, the permeability of PAC-16 gradation is most obviously affected by air voids, and the horizontal permeability and vertical permeability of PAC-10 specimen are more affected by thickness, at the same time, with the greater maximum nominal particle size and air voids, the greater the effect on the permeation rate.

S3, the effect of different distribution amounts of emulsified asphalt between the intermediate layer and lower layer on the permeability of the lower layer and interlayer bonding capacity is studied according to the feasibility of the actual construction process of the three-layer PA pavement, and based on the effect of different dosages of emulsified asphalt on an interlayer shear strength of the intermediate layer and lower layer and permeability of the lower layer, the dosage of emulsified asphalt between the intermediate layer and lower layer is determined, and the amount of interlayer emulsified asphalt of the intermediate layer and the lower layer is determined;

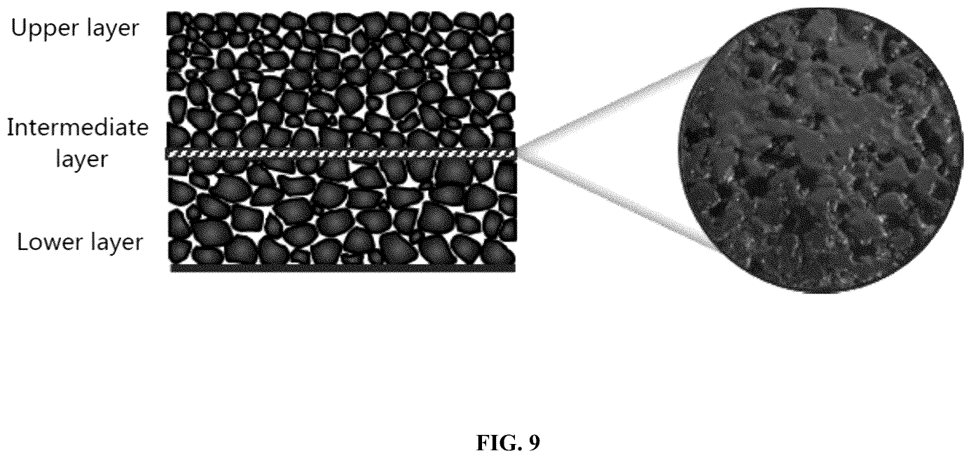

For the three-layer PA pavement in this embodiment, the bonding performance between the surface layers is improved by distributing the emulsified asphalt adhesive layer. As shown in FIG. 9, it is necessary to compare and analyze the effect of different dosages of emulsified asphalt on interlayer performance through permeability test and shear test.

The Marshall specimen with a diameter of 152.4 mm is prepared by porous asphalt mixture according to the previous thickness design, the steps are as follows: after the asphalt mixture of the lower layer is formed, the modified emulsified asphalt with different dosages (0, 0.15, 0.3, 0.45, 0.6 kg/m²) is evenly distributed on the upper surface, the technical indicators of the modified emulsified asphalt are shown in Table 8. At the same time, the asphalt mixture of the intermediate layer and the upper layer is formed. A control group with three layers at the same time paving and forming is set up.

TABLE 8
Technical indicators of modified emulsified asphalt

| Technical indicators | Unit | Results | Requirements |
|---|---|---|---|
| Demulsification speed | — | Quick crack | Quick or medium |
| | | | crack |
| Ion charge | — | Cation (+) | Cation (+) |
| Engel's viscosity 50° C. | | 3.2 | 1-10 |
| Residual amount on the | % | 0.008 | <0.1 |
| sieve | | | |
| Evaporation solid | % | 58.4 | ≥50 |
| content | | | |

The interlayer shear strength of porous asphalt mixture is studied by MTS universal testing machine. Firstly, a cylinder specimen with a diameter of 100 mm is obtained by core sampling, the specimen is placed in a constant temperature box at 25° C. for at least 3 hours, after end, the specimen is placed in a mold to be fixed, the specimen is loaded by the MTS universal testing machine, the loading rate is controlled at 50 mm/min, and loaded to the specimen failure to obtain the maximum failure load, the interlayer shear strength of the specimen is calculated according to Formula (2).

$$τ = \frac{F}{A} \qquad ( 2 )$$

where τ is a shear strength (MPa); F is a maximum failure load (N); A is an interlayer contact area (mm²).

At the same time, the self-developed bidirectional permeameter is used to test the permeability performance. The test method is consistent with the method of S2.

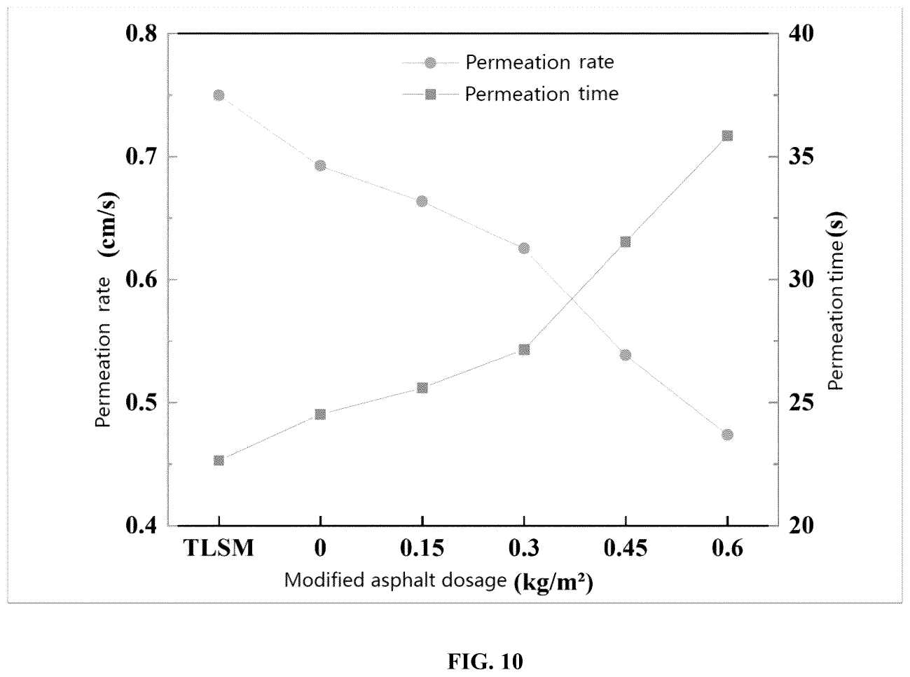

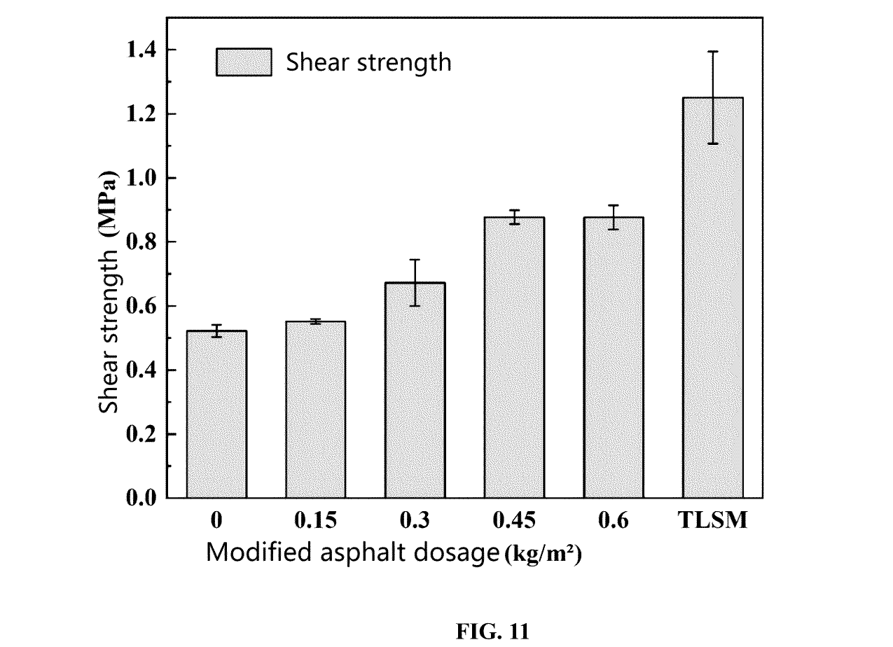

From FIG. 10 and FIG. 11, it can be seen that the water permeability coefficient shows a downward trend with the increase of the dosage of emulsified asphalt in the tack coat, when the dosage of emulsified asphalt in the tack coat is 0.45 kg/m², the decrease is greater, and the water permeability coefficient is only 77.76% of that without tack coat oil, and when the dosage of emulsified asphalt in the tack coat is 0.3 kg/m², the water permeability coefficient is 0.625 cm/s, which is 90.31% of that without tack coat oil.

With the increase of the amount of tack coat oil, the interlayer shear strength shows an upward trend, when the distributing amount of emulsified asphalt tack coat oil is 0.3 kg/m², the shear strength is 0.67 MPa, the shear strength is 28.8% higher than that without emulsified asphalt tack coat oil, when the distributing amount of tack coat oil exceeds 0.45 kg/m², the trend of shear strength increase is not obvious.

The comprehensive consideration is that the distributing amount of emulsified asphalt is 0.3 kg/m², the shear strength is greatly improved compared with that without distributing, and the good permeability can be guaranteed.

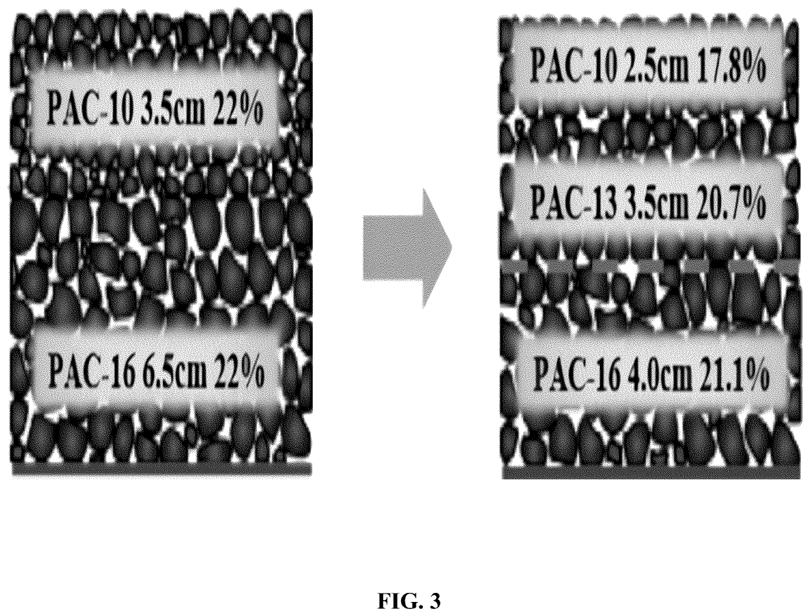

Based on the principle of equal permeation rate, taking the upper layer of the double-layer porous structure as a reference, the permeation rate of the upper layer of the optimized three-layer PA structure is 0.6791 cm/s, and the permeation rate of the intermediate layer is 0.6791 cm/s; after considering the effect of interlayer emulsified asphalt on the permeation rate, the conversion permeation rate of the lower layer is 0.8279 cm/s. The optimized three-layer PA pavement structure is shown in FIG. 3. The air voids of the optimized three-layer PA pavement structure are reduced.

S4, a relationship between the air voids and the permeation rate of the lower layer PA pavement under a given amount of emulsified asphalt is studied, based on the principle that the permeation rate of each layer of the three-layer PA pavement is equal, the air voids size of the lower layer are determined, and the thickness and material composition of the final three-layer PA pavement are determined.

Aiming at the determination of the air voids of the optimized three-layer PA pavement structure, a prediction model is established with the maximum nominal particle size, thickness and permeation rate as independent variables and the air voids as the dependent variable. By using the prediction model of permeation rate, the original sample data is kept unchanged, and the air voids of the independent variable and the permeation rate of the dependent variable are exchanged to establish the air voids prediction model.

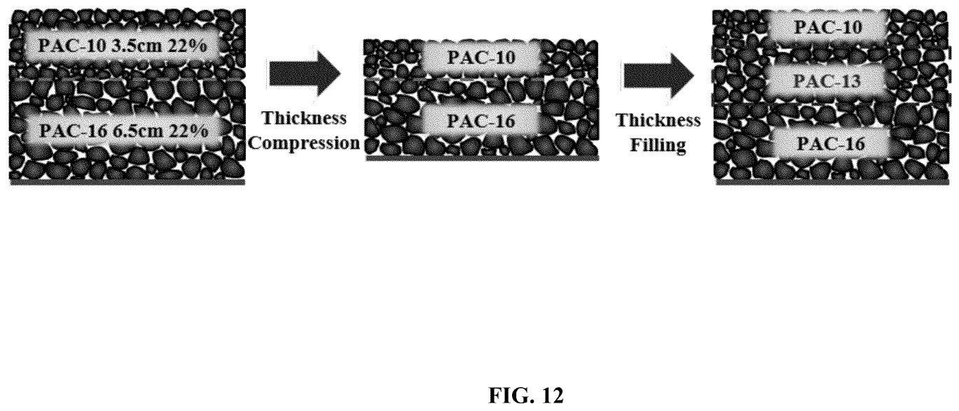

The optimized void clogging is more concentrated in the surface layer, while the surface layer is thinner, and the repair efficiency after the clogging is higher; the connectivity air voids of the three-layer structure can be improved, and the total air voids can be decreased to better maintain the durability of the optimized three-layer PA pavement pore structure. The structural optimization schematic diagram is shown in FIG. 12.

The air voids, thickness and maximum nominal particle size of each structural layer of the conventional double-layer PAC pavement are known, and the permeation rate of each structural layer in the highway test section is predicted as Table 9 according to the prediction model of permeation rate.

TABLE 9
Prediction results of permeation rate
of double-layer PAC pavement structure

| | Thickness | Air | Prediction results of |
|---|---|---|---|
| Particle size gradation | (cm) | voids | permeation rate(cm/s) |
| PAC-10 | 3.5 | 22% | 0.6791 |
| PAC-16 | 6.5 | 22% | 0.7399 |

For the air voids prediction model, the air voids results of part data in the training set are randomly predicted as shown in Table 10, and the evaluation results of each evaluation index are shown in Table 11. It can be seen from Table 11 that the determination coefficient R² of the prediction results of the air voids model is 0.907, and the prediction results are more accurate.

TABLE 10
Prediction results of part test data
with air voids as dependent variable

| | Particle | | Permeation | | Prediction |
|---|---|---|---|---|---|
| Order | size | Thickness | rate | Air | results of |
| number | gradation | (cm) | (cm/s) | voids | air void |
| 1 | PAC-10 | 2 | 0.7077 | 15.00% | 15.33% |
| 2 | PAC-10 | 2 | 0.7721 | 18.00% | 18.83% |
| 3 | PAC-13 | 5 | 0.6444 | 15.00% | 14.70% |
| 4 | PAC-13 | 5 | 0.5612 | 18.00% | 18.87% |
| 5 | PAC-13 | 4 | 0.7089 | 24.00% | 23.64% |
| 6 | PAC-10 | 3 | 0.6291 | 15.00% | 14.71% |
| 7 | PAC-16 | 5 | 0.8612 | 21.00% | 21.60% |
| 8 | PAC-10 | 4 | 0.6794 | 21.00% | 21.41% |
| 9 | PAC-16 | 6 | 0.8940 | 24.00% | 23.55% |
| 10 | PAC-13 | 3 | 0.6785 | 15.00% | 15.74% |
| 11 | PAC-10 | 4 | 0.7173 | 24.00% | 23.71% |
| 12 | PAC-16 | 5 | 0.8492 | 21.00% | 21.30% |

TABLE 11
Model evaluation results with air voids as dependent variable

| | MSE | RMSE | MAE | MAPE | R² |
|---|---|---|---|---|---|
| Training set | 0 | 0.001 | 0.001 | 0.117 | 1 |
| Test set | 0.001 | 0.018 | 0.014 | 3.387 | 0.907 |

### Performance Evaluation of a Three-Layer Porous Asphalt Mixture

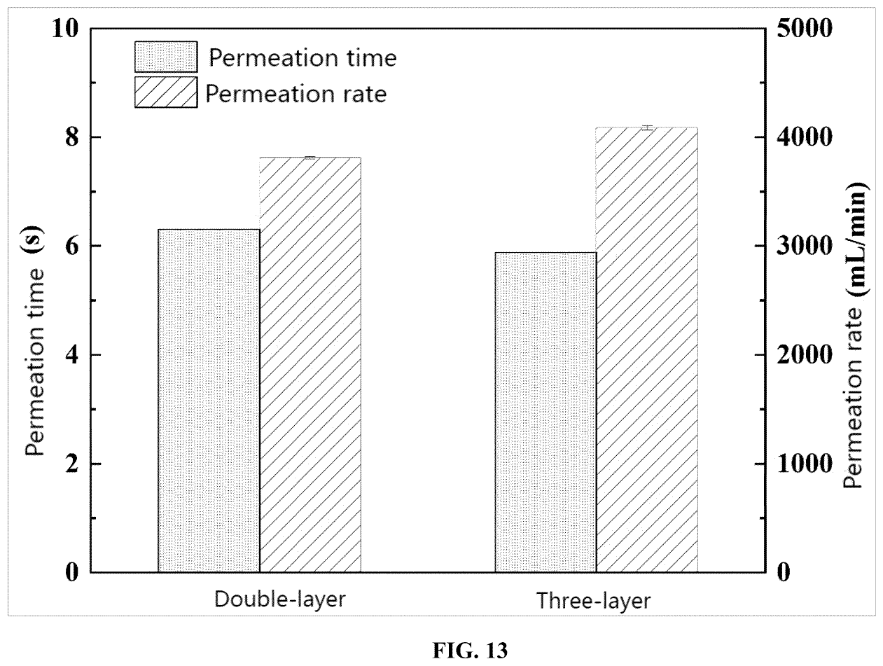

The permeability of porous asphalt mixture is evaluated by permeameter, and a larger permeation rate means high permeability. It can be seen from FIG. 13 that the permeation rate of porous asphalt mixture before and after optimization is 3809.2 mL/min and 4083.3 mL/min. This is a three-layer porous asphalt pavement structure based on the equal permeation rate design before and after the design optimization, while reducing the air voids, it guarantees its permeability and improves the road performance of the surface layer.

The key road performances such as high temperature, low temperature, water stability and anti-scatter properties of the optimized porous asphalt mixture have been improved in different degrees.

Finally, it should be noted that the above examples are merely used for describing the technical solutions of the present invention, rather than limiting the same. Although the present invention has been described in detail with reference to the preferred examples, those of ordinary skill in the art should understand that the technical solutions of the present invention may still be modified or equivalently replaced. However, these modifications or substitutions should not make the modified technical solutions deviate from the spirit and scope of the technical solutions of the present invention.

What is claimed is:

1. A method for optimizing double-layer PA pavement structure into three-layer structure based on equal permeation rate, comprising the following steps:
S1, studying a relationship between a pavement structure and a material composition segregation of different nominal maximum particle sizes and different paving thickness, determining a multiple relationship between paving thickness and nominal maximum particle size, and compressing the thickness of an upper layer and a lower layer of a double-layer PA pavement, and obtaining the thickness and the nominal maximum particle size of an added layer by combining a principle that the total thickness of the pavement before and after optimization is unchanged, so as to form an initial three-layer PA pavement;
S2, studying the effect of air voids, paving thickness and nominal maximum particle size on a permeation rate, and establishing a prediction model of permeation rate based on an XGBoost algorithm; calculating the air voids of the upper layer and an intermediate layer of the initial three-layer PA pavement according to the permeation rate of the upper layer of the double-layer PA pavement before optimization, and completing an optimization design of the material composition of the upper layer and the intermediate layer;
S3, studying the effect of different distribution amounts of emulsified asphalt between the intermediate layer and lower layer on the permeability of the lower layer and interlayer bonding capacity according to the feasibility of the actual construction process of the three-layer PA pavement, and based on the effect of different dosages of emulsified asphalt on an interlayer shear strength of the intermediate layer and lower layer and permeability of the lower layer, determining the dosage of emulsified asphalt between the intermediate layer and lower layer, and determining the amount of interlayer emulsified asphalt of the intermediate layer and lower layer;
S4, studying a relationship between the air voids and the permeation rate of the lower layer PA pavement under a given amount of emulsified asphalt, based on the principle that the permeation rate of each layer of the three-layer PA pavement is equal, determining the air voids size of the lower layer, and determining the thickness and material composition of the final three-layer PA pavement.

2. The method for optimizing double-layer PA pavement structure into three-layer structure based on equal permeation rate according to claim 1, S1 specifically comprises:
S11, quantitatively evaluating an internal structure distribution and segregation characteristics of double-layer PA pavement with different thickness according to a segregation degree of vertical structure, a coefficient of uneven distribution of particles and an coefficient variation of the vertical distribution of particles, and determining the multiple relationship between paving thickness and nominal maximum particle size;
S12, according to the multiple relationships between the paving thickness and the nominal maximum particle size, keeping the nominal maximum particle size of the upper layer and lower layer of the double-layer PA pavement unchanged, and compressing the thickness of the upper layer and lower layer, at the same time, combining with a principle that the total thickness of the pavement before and after optimization is unchanged, obtaining the thickness and the nominal maximum particle size of the added layer, and forming the initial three-layer PA pavement.

3. The method for optimizing double-layer PA pavement structure into three-layer structure based on equal permeation rate according to claim 2, the specific steps of S2 are:
S21, establishing the prediction model of permeation rate based on the XGBoost algorithm according to the relationship between air voids, paving thickness, nominal maximum particle size and permeation rate, at the same time, obtaining the permeation rate of the upper layer of the original double-layer PA pavement according to the real experiment;
S22, exchanging the independent variable air voids and the dependent variable permeation rate of the prediction model of permeation rate in the XGBoost algorithm to form an air voids prediction model based on the permeation rate, the nominal maximum particle size and the paving thickness to predict the air voids size, according to the principle that the permeation rate before and after pavement optimization is unchanged, putting the permeation rate of the upper layer of the double-layer PA pavement, and the paving thickness and the nominal maximum particle size of the upper layer and intermediate layer of the initial three-layer PA pavement obtained in S1 into the air voids prediction model as input data, obtaining the air voids of the upper layer and intermediate layer of the initial three-layer PA pavement.

4. The method for optimizing double-layer PA pavement structure into three-layer structure based on equal permeation rate according to claim 1, the relationship between the permeation rate and different dosages of emulsified asphalt is obtained by using the initial permeation rate of the three-layer PA pavement in S3, and at the same time, the relationship between different dosages of emulsified asphalt and the interlayer shear strength between the layers is also obtained to determine an optimal amount of emulsified asphalt;
the calculation formula of interlayer shear strength is as follows:
$$τ = \frac{F}{A}$$
where τ is a shear strength; F is a maximum failure load; A is an interlayer contact area.

5. The method for optimizing double-layer PA pavement structure into three-layer structure based on equal permeation rate according to claim 4, S4 specifically comprises:
based on the principle that the permeation rate of each layer of the three-layer PA pavement is equal, obtaining the relationship between the permeation rate and the given emulsified asphalt, and then obtaining the relationship between the dosage of emulsified asphalt and the air voids, putting the paving thickness, the nominal maximum particle size, the permeation rate and the given emulsified asphalt amount in S2 into the air voids prediction model as input data to determine the air voids of the lower layer.

6. The method for optimizing double-layer PA pavement structure into three-layer structure based on equal permeation rate according to claim 1, the accuracy of the prediction model of permeation rate is evaluated by R², MSE, RMSE, MAE, and MAPE.
